(19) United States
(12) Patent Application Publication
(10) Pub. No.: US 2024/0010489 A1
(43) Pub. Date: Jan. 11, 2024

(54) MEMS DEVICE COMPRISING A DEFORMABLE STRUCTURE AND MANUFACTURING PROCESS OF THE MEMS DEVICE

(71) Applicant: STMICROELECTRONICS S.r.l., Agrate Brianza (IT)

(72) Inventors: Manuel RIANI, Como (IT); Gabriele GATTERE, CASTRONNO (IT); Federico VERCESI, Milano (IT)

(73) Assignee: STMICROELECTRONICS S.r.l., Agrate Brianza (IT)

(21) Appl. No.: 18/341,565

(22) Filed: Jun. 26, 2023

(30) Foreign Application Priority Data
Jul. 11, 2022 (IT) 102022000014542

(51) Int. Cl. B81B 3/00; B81C 1/00

(52) U.S. Cl. CPC B81B 3/0021; B81C 1/0015; B81B 2203/0118; B81B 2203/0307; B81B 2203/0315; B81C 2201/0109; B81C 2201/0133

(57) ABSTRACT

A MEMS device comprising: a semiconductor body defining a main cavity and forming an anchorage structure; and a first deformable structure having a first end and a second end that are opposite to one another along a first axis, the first deformable structure being fixed to the anchorage structure via the first end so as to be suspended over the main cavity. The second end is configured to oscillate, with respect to the anchorage structure, along a second axis. The first deformable structure comprises a main body having a first outer surface and a second outer surface, and a piezoelectric structure, which extends over the first outer surface. The main body comprises a bottom portion and a top portion that delimit along the second axis a first buried cavity aligned with the piezoelectric structure along the second axis, wherein a maximum thickness of the top portion of the main body along the second axis is smaller than a minimum thickness of the bottom portion of the main body along the second axis.

### BACKGROUND

### Technical Field

The present disclosure relates to a MEMS device comprising a deformable structure and to a manufacturing process of the MEMS device.

### Description of the Related Art

As is known, piezoelectric materials enable conversion from electrical energy to mechanical energy, and vice versa.

In particular, MEMS (MicroElectroMechanical Systems) devices are known that have one or more deformable structures (e.g., structures suspended over cavities, such as cantilevers), with piezoelectric layers (e.g., of the thin-film type), and that operate as actuators, sensors, or energy harvesters.

In fact, when MEMS devices function as sensors or energy harvesters, these deformable structures undergo mechanical deformation in an elastic way on account of external forces acting on them, and this causes respective elastic mechanical deformations of the piezoelectric layers, which, by the forward piezoelectric effect, are biased, generating a difference of electrical potential across them, which is acquired for purposes of measurement (sensor application) or else for driving an electrical load (energy-harvesting application). Instead, when MEMS devices function as actuators, the piezoelectric layers are electrically biased (e.g., by applying a difference of electrical potential across them) so that, by the reverse piezoelectric effect, they will undergo mechanical deformation in an elastic way, generating a respective elastic mechanical deformation of the deformable structures, which causes the latter to exert forces of actuation on the external environment.

An example of deformable structure of a known type comprised in a known MEMS device is represented in FIG. 1, designated by the reference 10, in a triaxial Cartesian system defined by an axis X, an axis Y, and an axis Z, which are mutually orthogonal. In detail, FIG. 1 shows the deformable structure 10 in a resting condition, i.e., in the absence of supply of electrical biasing or of application of an external force.

In particular, the deformable structure 10 (e.g., a cantilever) has its main extension in a direction of main extension (represented by way of example parallel to the axis X in FIG. 1) and has a first end 10′ and a second end 10″ opposite to one another in the direction of main extension. For instance, the deformable structure 10 may be fixed (thus constrained), via the first end 10′, to an anchorage structure (or fixed structure) of the MEMS device (not shown), and may be coupled, via the second end 10″, to a seismic mass of the MEMS device, not shown and configured to oscillate in a direction of oscillation orthogonal to the direction of main extension and here considered by way of example parallel to the axis Z.

The deformable structure 10 comprises a main body 12 (of semiconductor material such as silicon) having a first surface 12a and a second surface 12b opposite to one another in the direction of oscillation (i.e., along the axis Z), and a piezoelectric structure 14, which extends on the first surface 12a. In detail, the main body 12 is full; i.e., it does not have buried cavities. The second surface 12b forms a bottom surface 10b of the deformable structure 10 whereas the piezoelectric structure 14 defines a top surface 10a of the deformable structure 10.

In greater detail and in a way not shown, the piezoelectric structure 14 may comprise a first electrode and a second electrode of conductive material (e.g., metal such as silver or gold) and a piezoelectric layer of piezoelectric material (e.g., PZT), which is arranged, along the axis Z, between the first and second electrodes. For instance, the first electrode extends on the first surface 12a between the piezoelectric layer and the main body 12, whereas the second electrode extends on the opposite side of the piezoelectric layer with respect to the first electrode.

The deformable structure 10 has a neutral plane 16 that is the locus of the points where the normal stress consequent upon a bending load along the axis Z is zero. In detail, the neutral plane 16 is substantially coincident with a midplane of the deformable structure 10, parallel to the plane XY. In other words, the neutral plane 16 is substantially equidistant from the top surface 10a and the bottom surface 10b of the deformable structure 10, given that generally the thickness along the axis Z of the piezoelectric structure 14 is much smaller (e.g., smaller by approximately 5%) than the thickness, along the axis Z, of the main body 12 and the elastic properties of the piezoelectric structure 14 do not differ too much from those of the main body 12.

The MEMS device including the deformable structure 10 may thus be used both as sensor or energy harvester (by acquiring, between the first and second electrodes, the difference of electrical potential induced in the piezoelectric layer by external forces acting in a direction parallel to the axis Z, which cause deflection of the deformable structure 10 along the axis Z), and as actuator (by biasing the piezoelectric layer to cause deformation thereof and, consequently, deflection of the deformable structure 10 along the axis Z).

FIG. 2 shows, instead, the deformable structure 10 in a condition of deformation, i.e., in the presence of supply of electrical biasing or of application of an external force. In FIG. 2 the deformable structure 10 is in a position of deformation different from a resting position of the deformable structure 10 in FIG. 1. In the example shown in FIG. 2, where the first end 10′ is constrained to the anchorage structure, whereas the second end 10″ is free to oscillate (e.g., it oscillates on account of the oscillatory movement of the seismic mass coupled thereto and thus forms a tip of the cantilever), the first end 10′ is in the same position as in the resting condition, whereas the second end 10″ is in a position different from that of the resting condition and in particular presents a displacement (or mechanical deflection) Z′ along the axis Z. In other words, the deformable structure 10 is deflected along the axis Z (i.e., it has a bending moment, along the axis Z) in a way such as to cause displacement Z′ of the second end 10″ along the axis Z, and thus a rotation of the deformable structure 10 about the axis Y, identified in FIG. 2 via an angle of rotation θ. In detail, in the resting condition the ends 10′ and 10″ are mutually aligned along the axis Z, whereas in the condition of deformation the ends 10′ and 10″ are mutually misaligned along the axis Z, (i.e., they have a height different from one another along the axis Z) and are arranged apart from one another along the axis Z by a deformation distance (or, more simply, a deformation) equal to the displacement Z; further, the angle of rotation θ is, for example, defined between an axis parallel to the axis X and an axis tangential to the second end 10″ of the deformable structure 10.

As is known, the effectiveness of this MEMS device in the conversion of energy, whether it operates as actuator (from electrical energy to mechanical energy) or as sensor or energy harvester (from mechanical energy to electrical energy), is expressed via an electromechanical coupling factor (or coefficient, parameter) EMCF_{ψ}. In particular, when the MEMS device operates as actuator the mathematical relation Z′∝φ·ΔV applies (where ΔV is the difference of potential supplied across the piezoelectric layer, ψ is the EMCF, and Z′ is the displacement generated by the reverse piezoelectric effect), and when the MEMS device operates as sensor or energy harvester, the mathematical relation Q∝φ·Z′ applies (where Z′ is the displacement caused by the external forces acting along the axis Z, ψ is the EMCF, and Q is the charge generated by the forward piezoelectric effect). Consequently, when the MEMS device operates as actuator, the displacement Z′ is proportional to the EMCF_{ψ}, when the MEMS device operates as sensor the detection current generated by the MEMS device is proportional to the EMCF_{ψ}, and when the MEMS device operates as energy harvester the electric power generated by the MEMS device is proportional to the square of the load current generated by the MEMS device (where the load current is proportional to the EMCF_{ψ}) and is therefore proportional to the square of the EMCF_{ψ}.

Consequently, it is evident how increasing the EMCF_{ψ} enables optimization of operation of the MEMS device. However, it is known how increasing the EMCF_{ψ} poses a series of difficulties.

In fact, the following mathematical relation applies:

$$ψ = {e}_{zx} \cdot {h}_{piezo - neutrax} \cdot \frac{1}{{L}_{beam}} \cdot \frac{d θ}{dZ} \cdot {A}_{cap} , with σ = \frac{1}{{L}_{beam}} \cdot \frac{d θ}{dZ}$$

where e_{zx} is a transverse effective piezoelectric constant of the deformable structure 10, h_{piezo-neutrax} is the distance between the piezoelectric structure 14 and the neutral plane 16 (e.g., measured between the neutral plane 16 and the surface of the second electrode that is opposite, along the axis Z, to the piezoelectric layer with respect to the second electrode), L_{beam} is the maximum length of the deformable structure 10 along the axis X, dθ/dZ is the rotation of the second end 10″ about the axis Y induced by the displacement Z′, and A cap is the area (measured in a direction parallel to a plane XY defined by the axes X and Y) of the capacitor formed by the piezoelectric structure 14.

In order to increase the EMCF it is possible to increase the following parameters:
e_{zx}, by identifying new materials with which to produce the deformable structure 10;
σ, which depends upon the way in which the deformable structure 10 bends and may be optimized but always implies a trade-off with optimization of other important parameters of the deformable structure 10 (e.g., A_{cap}, frequency of oscillation of the deformable structure 10, full-scale band of the MEMS device);
A_{cap}, by increasing the area dedicated to the piezoelectric structure 14, even though it may require a corresponding increase in the dimensions of the MEMS device and cause variations in important parameters of the deformable structure 10 (e.g., frequency of oscillation of the deformable structure 10, full-scale band of the MEMS device); and

h_{piezo-neutrax}; however, as the thickness of the main body 12 (of solid material, such as silicon) increases along the axis Z, also the stiffness and thus the resonance frequency of the MEMS device increases, causing a reduction of the effectiveness of operation of the MEMS device.

Generally, the known solutions that enable improvement of the EMCF_{ψ} exploit modifications to the materials or optimization of design of the deformable structure 10. For instance, this includes developing new high-performance piezoelectric materials (e.g., doping AlN with scandium or else PZT with niobium or manganese) or else improving the design to increase the sensitivity of the MEMS device (e.g., the shape of the deformable structure 10 that is tapered towards the second end 10″). However, the use of new materials requires a considerable effort of research and development, both in economic terms and in terms of timing, and the optimization of the design could have a different effect according to the effective application of the MEMS device, implying the need to reach compromises on important parameters or properties of the MEMS device (e.g., between sensitivity and strength and between full-scale band and maximum deformation).

### BRIEF SUMMARY

At least one embodiment of the present disclosure provides a MEMS device and a manufacturing process of the MEMS device, which will overcome the drawbacks of the prior art.

According to the present disclosure a MEMS device and a manufacturing process of the MEMS device are provided, as defined in the annexed claims.

In at least one embodiment, a MEMS device includes a semiconductor body defining a main cavity and forming an anchorage structure and a first deformable structure having a direction of main extension along a first axis, and a first end and a second end that are opposite to one another along the first axis. The first deformable structure is fixed to the anchorage structure via the first end so as to be suspended over the main cavity. The second end is configured to oscillate, with respect to the anchorage structure, in a direction of oscillation parallel to a second axis orthogonal to the first axis. The first deformable structure includes a main body having a first outer surface, a second outer surface opposite to the first outer surface along the second axis, and a piezoelectric structure extending over the first outer surface of the main body. The main body includes a bottom portion and a top portion that are coupled together and that delimit along the second axis a first buried cavity of the main body aligned with the piezoelectric structure along the second axis. The top portion of the main body defines the first outer surface of the main body and the bottom portion of the main body defining the second outer surface of the main body. The maximum thickness of the top portion of the main body along the second axis is smaller than the minimum thickness of the bottom portion of the main body along the second axis.

In at least one embodiment, a manufacturing process forms a MEMS device. The MEMS device includes a semiconductor body that defines a main cavity and forms an anchorage structure. The MEMS device includes a first deformable structure, having a direction of main extension along a first axis, and a first end and a second end that are opposite to one another along the first axis. The first deformable structure is fixed to the anchorage structure via the first end so as to be suspended over the main cavity. The second end is configured to oscillate with respect to the anchorage structure in a direction of oscillation parallel to a second axis orthogonal to the first axis. The manufacturing process includes the steps of forming, on a first surface of a substrate of semiconductor material, a main body of the first deformable structure including semiconductor material and having a first outer surface and a second outer surface opposite to one another along the second axis. The semiconductor body includes the substrate. The process includes the step of forming, in the main body, a first buried cavity delimited along the second axis by a bottom portion and by a top portion of the main body, coupled together. The top portion of the main body defines the first outer surface of the main body. The bottom portion of the main body defines the second outer surface of the main body. The maximum thickness of the top portion of the main body along the second axis is smaller than the minimum thickness of the bottom portion of the main body along the second axis. The process includes the step of forming, on the first outer surface, a piezoelectric structure of the first deformable structure. The piezoelectric structure is aligned along the second axis to the first buried cavity. The process includes the step of forming in the substrate, starting from a second surface of the substrate opposite to the first surface of the substrate along the second axis, the main cavity so as to define the anchorage structure and to have the first deformable structure fixed to the anchorage structure via the first end and suspended over the main cavity.

### BRIEF DESCRIPTION OF THE SEVERAL VIEWS OF THE DRAWINGS

For a better understanding of the present disclosure, a preferred embodiment is now described, purely by way of non-limiting example, with reference to the attached drawings, wherein:

FIG. 1 is a longitudinal sectional view of a deformable structure of a known type of a MEMS device, in a resting condition of the deformable structure;

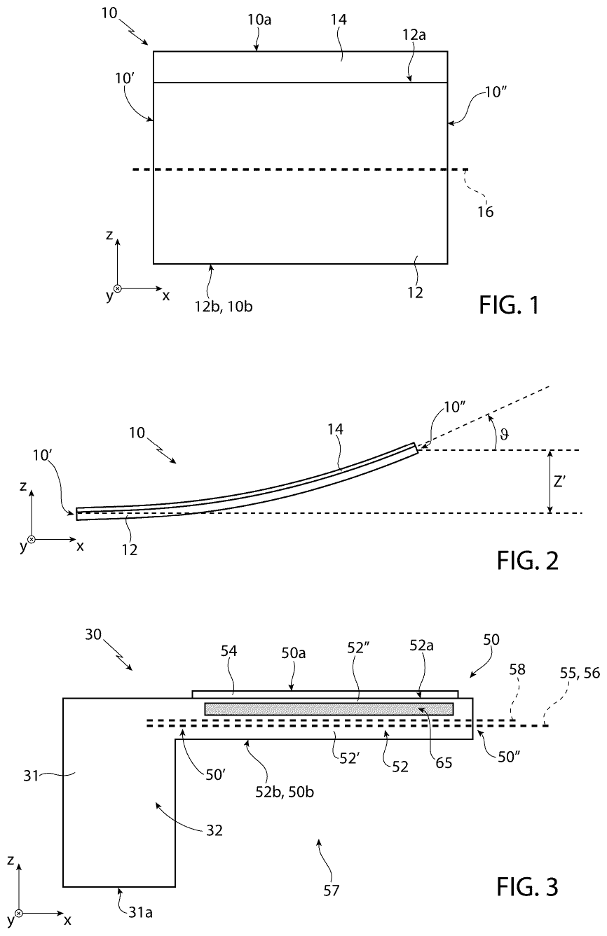

FIG. 2 is a longitudinal sectional view of the deformable structure of FIG. 1, in a condition of deformation thereof;

FIG. 3 is a longitudinal sectional view (taken along a line of section A-A represented in FIG. 6) of a MEMS device comprising a deformable structure, in a resting condition of the deformable structure and according to an embodiment of the MEMS device;

FIG. 4 is a longitudinal sectional view (taken along the line of section A-A) of the deformable structure of FIG. 3, in its resting condition;

FIG. 5 is a cross-sectional view (taken along a line of section B-B represented in FIG. 6) of the deformable structure of FIG. 3, according to an embodiment of the MEMS device;

FIG. 6 is a top plan view with parts removed of the MEMS device of FIG. 3, according to an embodiment thereof;

FIG. 7 is a longitudinal sectional view (taken along the line of section A-A) of the MEMS device of FIG. 6, further comprising a seismic mass coupled to the deformable structure, in the resting condition of the deformable structure and according to an embodiment of the MEMS device; and

FIGS. 8A-8I are longitudinal sectional views along the line of section A-A, of respective steps of a manufacturing process of the MEMS device of FIG. 6, according to an embodiment.

### DETAILED DESCRIPTION

In the following description, certain details are set forth in order to provide a thorough understanding of various embodiments of devices, methods and articles. However, one of skill in the art will understand that other embodiments may be practiced without these details. In other instances, well-known structures and methods associated with, for example, image sensors, semiconductor fabrication processes, etc., have not been shown or described in detail in some figures to avoid unnecessarily obscuring descriptions of the embodiments.

Unless the context requires otherwise, throughout the specification and claims which follow, the word “comprise” and variations thereof, such as “comprising,” and “comprises,” are to be construed in an open, inclusive sense, that is, as “including, but not limited to.”

Reference throughout this specification to “one embodiment,” or “an embodiment” means that a particular feature, structure or characteristic described in connection with the embodiment is included in at least one embodiment. Thus, the appearances of the phrases “in one embodiment,” or “in an embodiment” in various places throughout this specification are not necessarily referring to the same embodiment, or to all embodiments. Furthermore, the particular features, structures, or characteristics may be combined in any suitable manner in one or more embodiments to obtain further embodiments.

The headings are provided for convenience only, and do not interpret the scope or meaning of this disclosure or the claims.

The sizes and relative positions of elements in the drawings are not necessarily drawn to scale. For example, the shapes of various elements and angles may not be drawn to scale, and some of these elements may be enlarged and positioned to improve drawing legibility. Further, the particular shapes of the elements as drawn are not necessarily intended to convey any information regarding the actual shape of particular elements, and have been selected solely for ease of recognition in the drawings. Geometric references are not intended to refer to ideal embodiments. For example, a reference to square-shaped does not mean that an element has a geometrically perfect square shape.

In particular, the representations in the figures are made with reference to a triaxial Cartesian system defined by an axis X (or first axis X), an axis Z (or second axis Z), and an axis Y (or third axis Y), orthogonal to one another.

In the ensuing description, elements common to the different embodiments are designated by the same reference numbers.

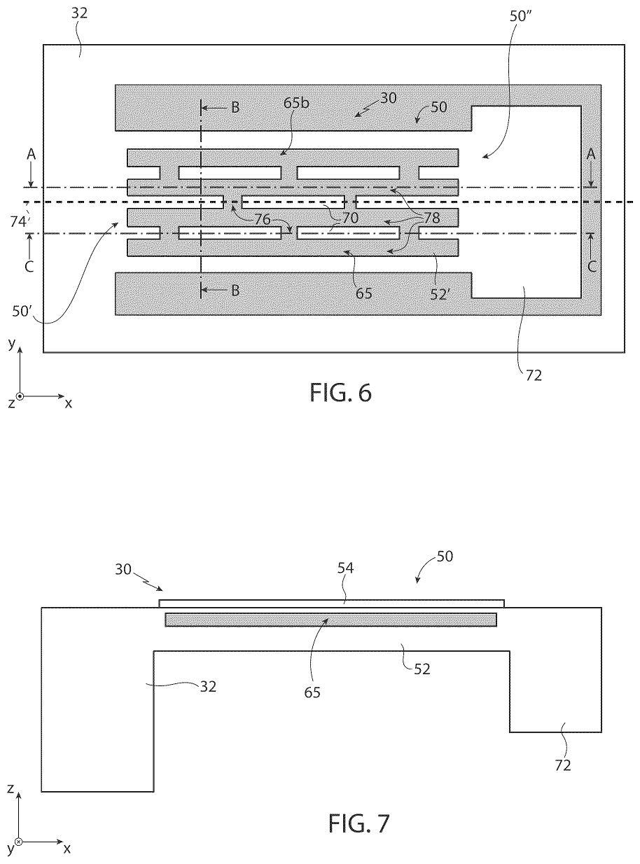

FIG. 3 shows a MEMS (MicroElectroMechanical Systems) device 30 formed in a semiconductor body 31 (of semiconductor material such as silicon) of the MEMS device 30.

The semiconductor body 31 defines an anchorage structure (or fixed structure or supporting structure) 32, which laterally delimits a main cavity 57 (which, for example, faces a bottom surface 31a of the semiconductor body 31).

The MEMS device 30 further comprises one or more deformable structures 50 coupled to the anchorage structure 32 and elastically suspended over the main cavity 57. In what follows, reference is made by way of example to the case where the MEMS device 30 comprises just one deformable structure 50 (also referred to as first deformable structure), even though it is evident that the MEMS device 30 may likewise comprise a number of deformable structures 50 (e.g., the first deformable structure and one or more second deformable structures, similar to the first deformable structure).

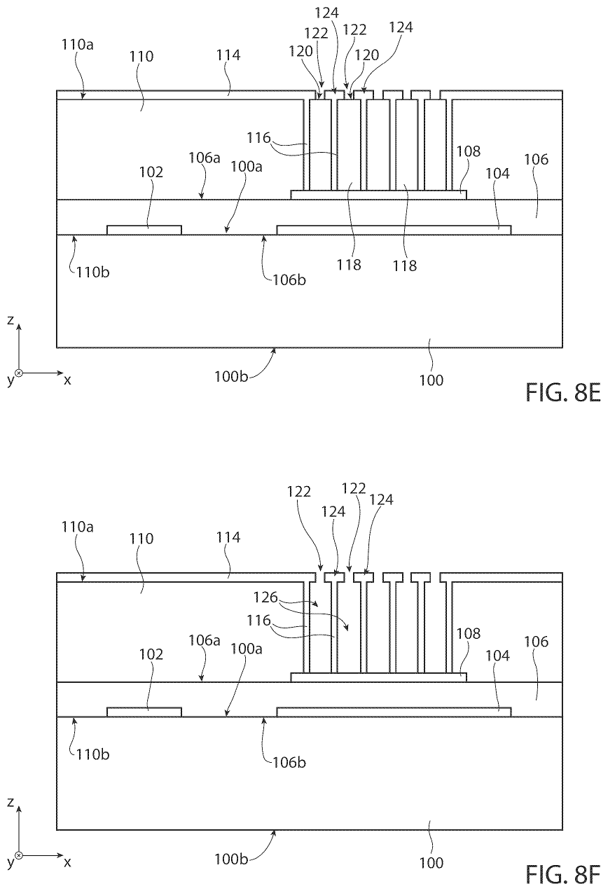

In detail, FIG. 3 is a longitudinal sectional view (e.g., taken along the line of section A-A shown in FIG. 6) that represent, in a plane XZ defined by the axes X and Z, the deformable structure 10 in a resting condition, i.e., in the absence of supply of electrical biasing or application of an external force and thus in the absence of deformation.

The deformable structure 50 (e.g., a cantilever) has its main extension in a direction of main extension (in FIG. 3 represented by way of example parallel to the axis X and designated by the reference 55) and has a first end 50′ and a second end 50″ opposite to one another in the direction of main extension 55.

In detail, the deformable structure 50 is fixed via the first end 50′ to the anchorage structure 32 so as to be suspended over the main cavity 57 and have the second end 50″ that may oscillate in a direction of oscillation orthogonal to the direction of main extension and here considered by way of example parallel to the axis Z. In greater detail, the deformable structure 50 and the anchorage structure 32 are monolithic.

The deformable structure 50 may further be coupled via the second end 50″ to a seismic mass of the MEMS device 30 (optional and not shown in this FIG. 3, but designated in FIG. 6 by the reference 72), configured to oscillate itself in the direction of oscillation.

In particular, the deformable structure 50 comprises a main body 52 (may of semiconductor material such as silicon) having a first outer surface 52a and a second outer surface 52b opposite to one another in the direction of oscillation (i.e., along the axis Z), and a piezoelectric structure 54, which extends over the first outer surface 52a. The second outer surface 52b forms a bottom surface 50b of the deformable structure 50, while the piezoelectric structure 54 defines a top surface 50a of the deformable structure 50.

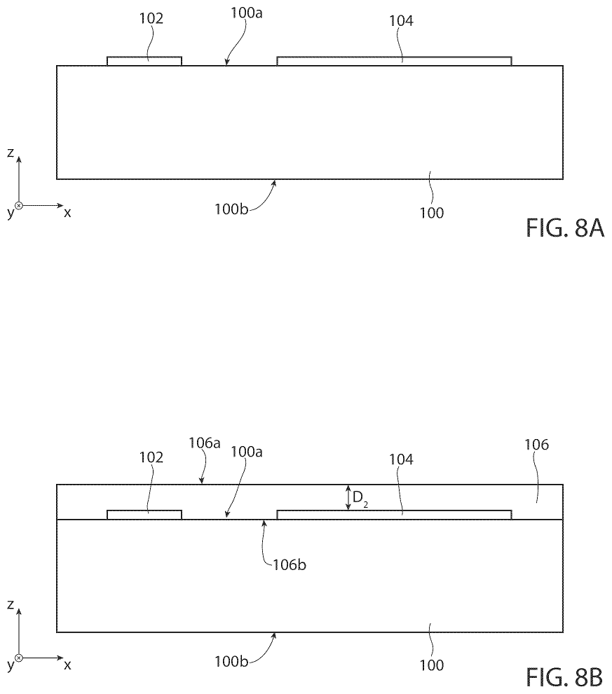

In greater detail and as illustrated more clearly in FIG. 4 (longitudinal sectional view along the line of section A-A), the piezoelectric structure 54 may comprise a first electrode 60 and a second electrode 61 of conductive material (e.g., metal such as silver or gold) and a piezoelectric layer 62 of piezoelectric material (e.g., PZT), which is arranged, along the axis Z, between the first and second electrodes 60, 61. For instance, the first electrode 60 extends on the first outer surface 52a between the piezoelectric layer 62 and the main body 52, whereas the second electrode 61 extends on the opposite side of the piezoelectric layer 62 with respect to the first electrode 60.

With reference once again to FIG. 3, the main body 52 comprises one or more buried cavities 65, which extend in an area corresponding to the first outer surface 52a of the main body 52. In what follows reference is made by way of example to the case where a buried cavity 65 is present (also referred to as first buried cavity), even though it is evident that there may likewise be present a number of buried cavities 65 (e.g., in addition to the first buried cavity also one or more second buried cavities similar to the first buried cavity and arranged alongside, i.e., laterally with respect to, the first buried cavity, along the axis X or Y, so as to be themselves aligned, along the axis Z, with the piezoelectric structure 54).

In particular, the buried cavity 65 is vertically aligned (i.e., aligned, along the axis Z) with the piezoelectric structure 54. For instance, the buried cavity 65 is arranged centrally with respect to the piezoelectric structure 54 (i.e., a center of the buried cavity 65 and a centroid of the piezoelectric structure 54 and, more in particular, of the piezoelectric layer 62, are mutually aligned, along the axis Z). In the example shown in FIGS. 3 and 4, the buried cavity 65 has a maximum width L_{c}, measured along the axis X, that is smaller than a maximum width Lₚ, measured along the axis X, of the piezoelectric structure 54 (e.g., of the piezoelectric layer 62); however, the maximum width L_{c}, may also be greater than, or equal to, the maximum width Lₚ.

The buried cavity 65 extends within the main body 52 so as to be buried in the main body 52. In particular, the main body 52 comprises a bottom portion (or first portion of main body) 52′ and a top portion (or second portion of main body) 52″ that are opposite to one another, along the axis Z, with respect to the buried cavity 65 and that delimit, along the axis Z, the buried cavity 65. The top portion 52″ and the bottom portion 52′ of the main body 52 define, respectively, a first inner surface 65a and a second inner surface 65b of the main body 52, which are arranged facing the buried cavity 65 and opposite to one another along the axis Z relative to the buried cavity 65 so as to delimit, along the axis Z, the buried cavity 65 and to form, respectively, a top wall and a bottom wall of the buried cavity 65. In particular, the buried cavity 65 is delimited laterally (i.e., in a direction parallel to the plane XY) by lateral portions 52′″ of the main body 52, shown in FIG. 4, which join together the top portion 52″ and the bottom portion 52′ of the main body 52.

The buried cavity 65 extends in the main body 52 so as to be closer to the first outer surface 52a of the main body 52 than to the second outer surface 52b of the main body 52. In other words, a maximum thickness D₁ of the top portion 52″ of the main body 52, measured along the axis Z, is smaller than a minimum thickness D₂ of the bottom portion 52′ of the main body 52 along the axis Z.

In greater detail, the first inner surface 65a is arranged apart from the first outer surface 52a of the main body 52 at most by a maximum distance D₁ (which is the maximum thickness, along the axis Z, of the top portion 52″ of the main body 52) and the second inner surface 65b is arranged apart from the second outer surface 52b of the main body 52 at least by a minimum distance D₂ (which is the minimum thickness, along the axis Z, of the bottom portion 52′ of the main body 52), with D₁<D₂. For instance, the buried cavity 65 has a maximum height H, measured along the axis Z (e.g., between the first and second inner surfaces 65a, 65b), which is comprised between approximately 2 μm and approximately 80 μm; further, the maximum thickness D₁ may be comprised between approximately 2 μm and approximately 80 μm and the minimum thickness D₂ may be comprised between approximately 4 μm and approximately 82 μm so that the sum of D₁, H, and D₂ is for example less than approximately 85 μm. For instance, D₁=5 μm, H=10 μm, D₂=15 μm; D₁=4 μm, H=20 μm, D₂=20 μm; D₁=2 μm, H=5 μm, D₂=10 μm.

The deformable structure 50 has a neutral plane. By “neutral plane” is meant the locus of the points in which the normal stress consequent upon a bending load along the axis Z is zero. In other words, in the case of mechanical deformation of the deformable structure 50, the stress and deformation are zero along the neutral plane (which thus joins the points of the deformable structure 50, which, in the case of deformation of the latter along the axis Z, do not undergo any longitudinal stress or deformation). In the absence of deformation of the deformable structure 50, the neutral plane is parallel to a plane XY defined by the axes X and Y and is thus orthogonal to the axis Z. In the longitudinal sectional views of FIGS. 3 and 4, the neutral plane is represented via a neutral axis corresponding to the intersection of the neutral plane with the plane XZ of the cross-section represented, and is designated by the reference 56. As may be seen, the neutral axis is parallel to or coincident with the direction of main extension 55 (by way of example in FIG. 3 it is represented coinciding with the direction of main extension 55), and is thus parallel to the axis X.

Furthermore, the deformable structure 50 has a midplane that, in the absence of deformation of the deformable structure 50, is parallel to the plane XY. In particular, the midplane is equally spaced apart from the top surface 50a and from the bottom surface 50b of the deformable structure 50. In other words, in the absence of deformation of the deformable structure 50, the midplane is arranged apart from the top surface 50a of the deformable structure 50 by a first midplane distance Dₘ₁ and is arranged apart from the bottom surface 50b of the deformable structure by a second midplane distance Dₘ₂ equal to the first midplane distance Dₘ₁. In the longitudinal sectional views of FIGS. 3 and 4, the midplane is represented via a center-line axis corresponding to the intersection of the midplane with the plane XZ of the cross-section represented, and is designated by the reference 58. As may be seen, the center-line axis is parallel to or coincident with the direction of main extension 55 (in FIG. 3 it is represented by way of example as being parallel and not coinciding with the direction of main extension 55), and is thus parallel to the axis X.

The neutral plane 56 and the midplane 58 do not coincide with one another. For example, as shown in FIG. 3, the neutral plane 56 and the midplane 58 are offset from each other when the deformable structure 50 is in a resting position in which the deformable structure 50 is in an undeformed state. Consequently, in the absence of deformation of the deformable structure 50 they are parallel and do not coincide. In other words, in the absence of deformation of the deformable structure 50, the neutral plane 56 is arranged apart from the top surface 50a of the deformable structure 50 by a first neutral distance Dₙ₁ and is arranged apart from the bottom surface of the deformable structure 50 by a second neutral distance Dₙ₂ different from the first neutral distance Dₙ₁. In particular, Dₙ₁≠Dₘ₁ and Dₙ₂≠Dₘ₂ and, in greater detail, Dₙ₁>Dₙ₂. This is due to the fact that the buried cavity 65 arranged at the top surface 50a of the deformable structure 50 displaces the neutral plane 56 under the midplane 58 (i.e., towards the bottom surface 50b of the deformable structure 50) on account of the absence of solid material in the buried cavity 65.

In detail, the first neutral distance Dₙ₁ is the distance between the piezoelectric structure 54 and the neutral plane 56, previously denoted as h_{piezo-neutrax} Consequently, the presence of the buried cavity 65 makes it possible to increase h_{piezo-neutrax} and thus to increase the EMCF_{ψ} (calculated as described previously) with respect to the case where the buried cavity 65 is not present. However, since the buried cavity 65 presents a vacuum or air (but in any case is not filled with solid material such as silicon), this increase of h_{piezo-neutrax} does not affect the flexural stiffness of the deformable structure 50, which thus remains constant. Consequently, the presence of the buried cavity 65 makes it possible to increase the EMCF_{ψ} without altering the mechanical properties of the deformable structure 50 and thus the properties of operation of the MEMS device (e.g., the resonance frequency, full-scale band, etc.).

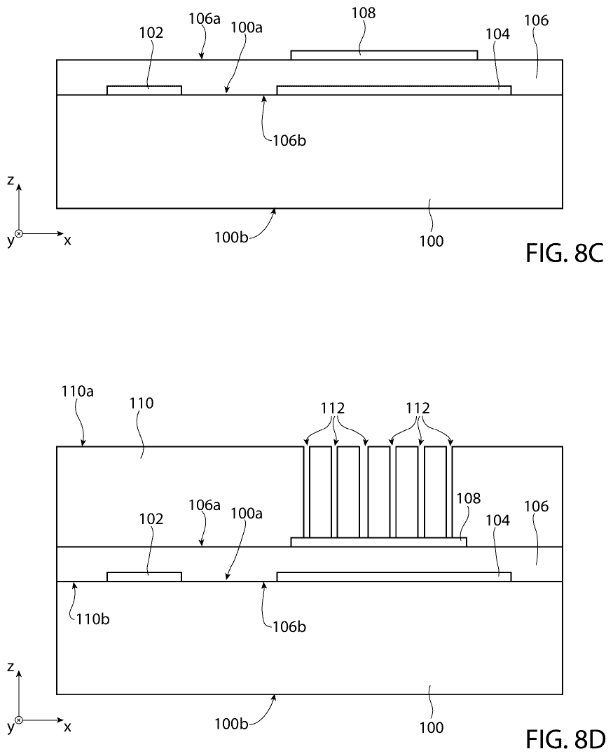

FIG. 5 shows, instead, in the plane YZ, a detail of a cross-sectional view of the deformable structure 50, taken along a line of section B-B represented in FIG. 6.

Optionally and as shown in FIG. 5, the main body 52 further comprises one or more supporting elements 70, which extend in the buried cavity 65 between the bottom portion 52′ and the top portion 52″ so as to join together, along the axis Z, the bottom portion 52′ and the top portion 52″. In this way, the stress and deformation of the bottom portion 52′ are transmitted in a more uniform way to the top portion 52″, thus both preventing the portions 52′ and 52″ from undergoing deformation in a way substantially independent of one another (thus running the risk of being deflected as two separate and parallel beams and not as a single beam) and preventing the possibility of collapse of the buried cavity 65 (i.e., preventing the first and second inner surfaces 65a, 65b of the main body 52 from bearing upon one another) when the deformable structure 50 undergoes excessive stress.

By way of non-limiting example, the supporting elements 70 may be columns (not shown, for example having a cylindrical shape with circular or polygonal base, e.g., square or hexagonal) or else supporting structures that, for example, substantially have the shape of a right parallelepiped (as shown in FIG. 6 and considered by way of example in what follows).

The number of the supporting elements 70 and their extension in a direction parallel to the plane XY are chosen heuristically in the stage of design of the MEMS device 30, taking into account factors, such as the maximum value of external force along the axis Z that the MEMS device is designed to withstand or generate and the desired stiffness of the deformable structure 50. Purely by way of non-limiting example, considering a plane parallel to the plane XY and passing through the buried cavity 65, the ratio between the total area of extension of the supporting elements and the total area of extension of the buried cavity 65 in the absence of supporting elements 70 may be less than approximately 5%.

In particular, FIG. 6 shows a top plan view (i.e., in a plane parallel to the plane XY), with parts removed, of an embodiment of the MEMS device 30, in which the supporting elements 70 are formed by the aforesaid supporting structures having by way of example the shape of a right parallelepiped. In detail, FIG. 6 does not show the piezoelectric structure 54 and the top portion 52″ so as to render visible the buried cavity 65 and the supporting structures (which are also designated in what follows by the reference 70).

In the embodiment of FIG. 6, the supporting structures 70 have respective directions of main extension (e.g., major side of the base of the right parallelepiped) that are parallel to the axis X.

The supporting structures 70 are aligned with one another in sets (or rows), each set having a respective axis of alignment 74 along which the supporting structures 70 of the set considered have the aforesaid directions of main extension (i.e., the supporting structures 70 lie along the respective axis of alignment 74). Consequently, the axes of alignment 74 of different sets of supporting structures 70 are parallel to one another and to the axis X.

Two sets of supporting structures 70 adjacent to one another (i.e., facing one another, without any further set interposed between them) laterally delimit, along the axis Y, a respective channel 78 that has its main extension parallel to the axis X. For instance, the axes of alignment 74 are spaced at equal distances apart along the axis Y so that the channels 78 have the same width along the axis Y.

In each set of supporting structures 70, the latter are arranged discretely along the respective axis of alignment 74 so as to have a respective opening 76 that arrange apart from one another two mutually adjacent supporting structures 70. The openings 76 arranged in communication with one another the channels 78, which form, together with the openings 76, the buried cavity 65.

In detail, the supporting structures 70 of each set are staggered, in a direction parallel to the axis Y, with respect to the supporting structures 70 of the adjacent set or of the pair of adjacent sets, so that two sets adjacent to one another have the openings 76 that are staggered with respect to one another in a direction parallel to the axis Y; i.e., they do not have the openings 76 that are coaxial (mutually aligned in a direction parallel to the axis Y). In other words, considering the sets of the supporting structures 70 as identified with a progressive numbering along the axis Y and in particular considering a set N and the sets N−1 and N+1 adjacent thereto, the openings 76 of the set N are staggered in a direction parallel to the axis Y with respect to the openings 76 of the sets N−1 and N+1. In greater detail, the openings 76 of sets that alternate with one another along the axis Y are coaxial (i.e., the openings 76 of the sets N−1 and N+1 are aligned with one another in a direction parallel to the axis Y, as are those of the sets N, N−2, N+2, which, however, are staggered with respect to those of the sets N−1 and N+1). This arrangement of the supporting structures 70 and of the openings 76 maximizes mechanical coupling of the top portion 52″ of the main body 52 to the bottom portion 52′ of the main body 52, thus improving the distribution of the stress along the deformable structure 50.

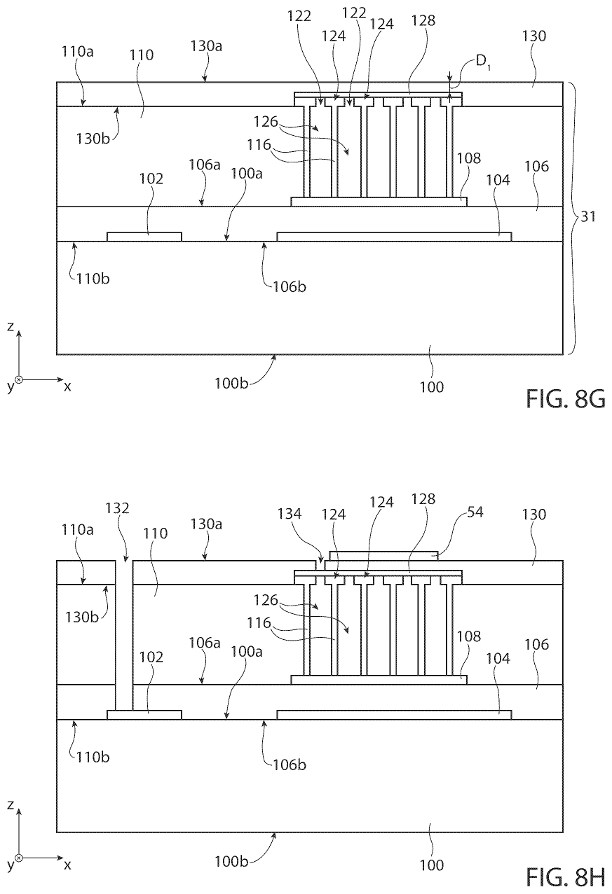

The embodiment of the MEMS device 30 shown in FIG. 6 has by way of example also the seismic mass, here designated by the reference 72 and coupled to the deformable structure at the second end 50″ (namely, it is monolithic with the deformable structure 32). This embodiment comprising the seismic mass 72 is also shown in FIG. 7, in longitudinal sectional view taken along the line of section A-A.

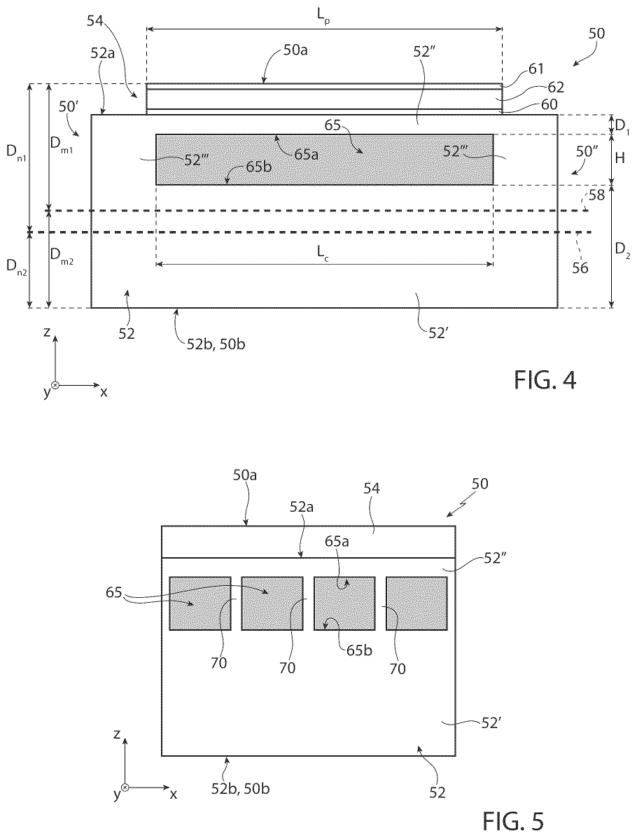

In general, the deformable structure 50 is deformable, and may thus pass from the resting condition to a condition of deformation. What has been illustrated and described with reference to FIG. 2 likewise applies also to the condition of deformation of the deformable structure 50, which is consequently not shown or described again in detail.

The MEMS device 30 including the deformable structure 50 may consequently be used both as sensor or energy harvester and as actuator (by biasing the piezoelectric layer to bring about deformation thereof, and consequently the deflection of the deformable structure 10 along the axis Z).

In particular, in the case of use as sensor or energy harvester and considering by way of example also the presence of the seismic mass 72, when the MEMS device 30 is subject to external forces acting in a direction parallel to the axis Z (e.g., due to accelerations to which the MEMS device 30 is subjected relative to the external environment), an elastic deformation is generated (in particular, bending) of the deformable structure 50 on account of the oscillatory movement of the seismic mass 72 relative to the anchorage structure 32. This elastic deformation of the deformable structure 50 generates a corresponding elastic deformation of the piezoelectric layer 62 and this in turn, by the forward piezoelectric effect, causes a difference of potential between the first and second electrodes 60, 61, which is acquired (to be measured in the case of use as sensor or to be used for driving an electrical load in the case of use as energy harvester).

Instead, in the case of use as actuator, a difference of potential is applied (e.g., via a biasing apparatus of a known type, external to the MEMS device 30 and electrically coupled to the latter) between the first and second electrodes 60, 61 so as to bias the piezoelectric layer 62 so that the latter, by the reverse piezoelectric effect, will undergo elastic deformation (thus generating a relative movement of the second end 50″ with respect to the first end 50′ and to the anchorage structure 32). This deformation may be used for purposes of actuation, in a way of itself known.

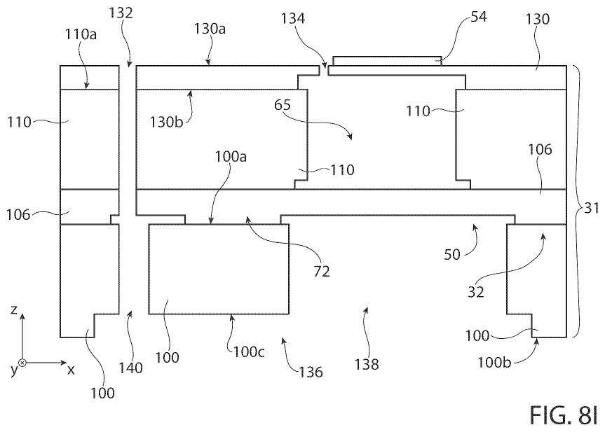

FIGS. 8A-8I show, in longitudinal sectional views along the line of section A-A, respective steps of a manufacturing process of the MEMS device 30.

In general, the manufacturing process comprises the steps of: forming, on a first surface 100a of a substrate 100 of semiconductor material, the main body 52 of the first deformable structure 50, of semiconductor material, where the semiconductor body 31 comprises the substrate 100; forming in the main body 52 the buried cavity 65, where the maximum thickness D₁ of the top portion 52″ of the main body 52 along the axis Z is smaller than a minimum thickness D₂ of the bottom portion 52′ of the main body 52 along the axis Z; forming on the first outer surface 52a the piezoelectric structure 54, aligned, along the axis Z, with the buried cavity 65; and forming in the substrate 100, starting from a second surface 100b of the substrate 100 opposite to the first surface 100a of the substrate 100, along the axis Z, the main cavity 57 so as to define the anchorage structure 32 and to have the first deformable structure 50 fixed to the anchorage structure 32 via the first end and suspended over the main cavity 57.

By way of example, the manufacturing process is described in greater detail in what follows with reference to the embodiment of the MEMS device 30 of FIG. 6 and to the case where the MEMS device 30 comprises the seismic mass 72. However, it is evident that the steps regarding manufacture of the seismic mass 72 may even be absent and that what has been described likewise applies also to the manufacture of the other embodiments of the MEMS device 30.

As shown in FIG. 8A, initially the substrate 100 of semiconductor material (e.g., silicon) is provided. The substrate 100 has the first surface 100a and the second surface 100b opposite to one another along the axis Z. For instance, the substrate 100 has a thickness along the axis Z comprised between approximately 250 μm and approximately 900 μm.

Formed on the first surface 100a of the substrate 100 are a first blocking layer 104 and a second blocking layer 102, of insulating material (e.g., oxide such as silicon oxide). The first and second blocking layers 104 and 102 are formed alongside one another along the axis X, for example so as to be at a distance from one another. In particular, the first and second blocking layers 104 and 102 are formed using techniques such as thermal oxidation, wet anodization, chemical vapor deposition (CVD), and plasma anodization.

In greater detail, an oxide layer is formed on the first surface 100a of the substrate 100, for example by carrying out a thermal process in oxygen atmosphere so as to get the oxygen to react with the silicon to create silicon oxide in on the first surface 100a of the substrate 100. On the oxide layer there is then formed a first mask (not illustrated and obtained using photolithographic techniques per se known, e.g., photoresist), which exposes a top surface of the oxide layer, leaving covered regions thereof that are arranged alongside one another and at a distance apart along the axis X and that are to become the first and second blocking layers 104 and 102. Next, an etch is carried out of the portions of the oxide layer exposed by the first mask, for example via wet etching (e.g., HF-based) or else plasma etching (e.g., using chlorine or fluorine compounds such as CF 4), to remove the portions of the oxide layer exposed by the first mask. Then, the first mask is removed, thus leaving the first and second blocking layers 104 and 102 on the first surface 100a of the substrate 100.

Alternatively, a first mask is formed that covers the first surface 100a of the substrate 100, leaving exposed regions of the first surface 100a that are arranged alongside one another and spaced apart at a distance along the axis X and that are to become the first and second blocking layers 104 and 102. The oxide layer is then formed, for example by carrying out a thermal process in oxygen atmosphere so as to get the oxygen to react with the silicon to create silicon oxide in the regions of the first surface 100a exposed by the first mask. Next, the first mask is removed, thus leaving the first and second blocking layers 104 and 102 on the first surface 100a of the substrate 100.

With reference to FIG. 8B, a first epitaxial layer 106 (of semiconductor material, e.g., silicon) is formed on the first surface 100a of the substrate 100 and on the first and second blocking layers 104 and 102. The first epitaxial layer 106 has a first surface 106a and a second surface 106b, opposite to one another along the axis Z, where the second surface 106b faces the substrate 100. In particular, formation of the first epitaxial layer 106 is performed via known techniques of epitaxial growth, for example via CVD (Chemical Vapor Deposition), PVD (Physical Vapor Deposition), or MBE (Molecular Beam Epitaxy). The first epitaxial layer 106 is designed to form the bottom portion 52′ of the main body 52, as discussed more fully hereinafter. In detail, the first epitaxial layer 106 has, on the first blocking layer 104, a thickness along the axis Z equal to the minimum thickness D₂ (e.g., a thickness measured along the axis Z between the first surface 106a of the first epitaxial layer 106 and the first blocking layer 104).

With reference to FIG. 8C, a first sacrificial layer 108 of insulating material (in particular oxide such as silicon oxide) is formed on the first epitaxial layer 106 (i.e., on its first surface 106a), as described with reference to FIG. 8A. In particular, the first sacrificial layer 108 overlies (i.e., is aligned vertically, along the axis Z, to) the first blocking layer 104. This is obtained, for example, via deposition of oxide on the first surface 106a of the first epitaxial layer 106, followed by etching of the oxide performed through a second mask (similar to the first mask) that covers a region of the top surface of the oxide layer that is overlies the first blocking layer 104 so as to remove the portions of oxide exposed by the second mask, thus defining the first blocking layer 104.

With reference to FIG. 8D, a second epitaxial layer 110 (of semiconductor material, e.g., silicon) is formed on the first surface 106a of the first epitaxial layer 106 and on the first sacrificial layer 108. This is obtained as described previously with reference to FIG. 8B. The second epitaxial layer 110 has a first surface 110a and a second surface 110b opposite to one another along the axis Z, where the second surface 110b faces the first epitaxial layer 106. For instance, the second epitaxial layer 110 has a thickness along the axis Z comprised between approximately 2 μm and approximately 80 μm (in general, a thickness approximately equal to the maximum height H). The second epitaxial layer 110 is designed to form the lateral portions 52′″ of the main body 52 and to house the buried cavity 65, as discussed more fully hereinafter.

FIG. 8D also shows formation, in the second epitaxial layer 110, of a plurality of first working trenches 112. In detail, the first working trenches 112 overlie the first sacrificial layer 108 and extend through the second epitaxial layer 110, from the first surface 110a until they reach the second surface 110b of the second epitaxial layer 110. The first working trenches 112 are formed via a first etch of the second epitaxial layer 110, carried out, for example, via wet etching (in particular of an anisotropic type, e.g., via KOH) or else plasma etching (e.g., with the Bosch process, i.e., using plasma with a base of chlorine or fluorine compounds). In greater detail, initially a third mask is formed (similar to the first mask), which covers the first surface 110a of the second epitaxial layer 110, leaving exposed regions of the first surface 110a through which the first etch will be carried out and which thus overlie the portions of silicon that will be removed to form the first working trenches 112. Next, the first etch is carried out through this third mask so as to remove selectively the portions of silicon exposed by the third mask. Finally, the third mask is removed from the second epitaxial layer 110 to obtain the structure shown in FIG. 8D.

With reference to FIG. 8E, a second sacrificial layer 114, of insulating material (in particular, oxide such as silicon oxide) is formed (as described with reference to FIG. 8A) on the second epitaxial layer 110 (i.e., on its first surface 110a) so as to fill the first working trenches 112. The second sacrificial layer 114 present in the first working trenches 112 forms sacrificial elements 116 of oxide, for example columns, which extend from the first sacrificial layer 108 to the first surface 110a of the second epitaxial layer 110. The portions of silicon arranged along the axis X between two sacrificial elements 116 adjacent to one another and overlying the first sacrificial layer 108 are in what follows referred to as sacrificial portions of the second epitaxial layer 110 and are designated by the reference 118. In particular, the second sacrificial layer 114 exposes, at least in part, the regions of the first surface 110a of the second epitaxial layer 110 that overlie the sacrificial portions 118. In what follows, these regions are also referred to as etching regions and are designated by the reference 120. In other words, the second sacrificial layer 114 covers the first surface 110a of the second epitaxial layer 110 but has etch openings 122 that expose the etching regions 120 and thus the sacrificial portions 118. In greater detail, these etch openings 122 have a width, measured along the axis X, smaller than the distance, measured along the axis X, between two sacrificial elements 116 adjacent to one another (e.g., the width of the etch openings 122 is comprised between approximately 0.3 μm and approximately 2 μm). In this way, for each sacrificial element 116, a respective part of the second sacrificial layer 114 extends also on part of the sacrificial portions 118 facing the sacrificial element 116 considered, forming, together with the latter, a respective sacrificial structure 124 that is substantially T-shaped or mushroom-shaped.

This is obtained, for example, via deposition of oxide performed uniformly over the first surface 110a of the second epitaxial layer 110 (i.e., also on the etching regions 120) and then via an etch used for selectively removing the oxide present on the etching regions 120 (e.g., via formation of a mask, similar to the first mask, on the second sacrificial layer 114 that covers the second sacrificial layer 114, leaving exposed the oxide regions overlying the etching regions 120, followed by execution of the etch through said mask).

With reference to FIG. 8F, the sacrificial portions 118 are removed to form respective second working trenches 126. In particular, the second working trenches 126 have a shape complementary to that of the sacrificial elements 116. In detail, this is obtained via a second etch (similar to the first etch and, for example, a KOH-based or TMAAH-based wet etch or else an XeF₂-based or SF₆-based plasma etch) carried out using the second sacrificial layer 114 as mask for selectively removing the sacrificial portions 118 exposed via the etch openings 122. The second etch is carried out starting from the etching regions 120 as far as the first sacrificial layer 108, which blocks the second etch preventing it from proceeding also in the underlying silicon. In this way, the first sacrificial layer 108 is exposed by the second etch.

With reference to FIG. 8G, a third sacrificial layer 128 of insulating material (in particular, oxide such as silicon oxide) is formed on the sacrificial structures 124 (more in general, on the sacrificial elements 116) so as to seal the second working trenches 126 by covering the etch openings 122. In particular, this is done by depositing an oxide layer on the second sacrificial layer 114, thus both on the sacrificial structures 124 and on the etch openings 122 (e.g., via CVD of materials such as TEOS or undoped silicon glass—USG). Then, the portions of the above oxide layer and of the second sacrificial layer 114 that extend over the first surface 110a of the second epitaxial layer 110 are removed, leaving intact, instead, the sacrificial structures 124 and the portion of the oxide layer that overlies the sacrificial structures 124 and the etch openings 122 and that is to form the third sacrificial layer 128. This is obtained, for example, by forming a fourth mask (similar to the first mask) on said oxide layer, which covers the portions of the oxide layer overlying the sacrificial structures 124 and of the etch openings 122 and exposes the remaining portions of the oxide layer, and subsequently carrying out an etch through the fourth mask to remove the portions of the oxide layer and of the second sacrificial layer 114 exposed by the fourth mask.

Furthermore, in FIG. 8G a third epitaxial layer 130 (of semiconductor material, e.g., silicon) is formed on the first exposed surface 110a of the second epitaxial layer 110 and on the third sacrificial layer 128. This is obtained as described previously with reference to FIG. 8B. The third epitaxial layer 130 has a first surface 130a and a second surface 130b opposite to one another along the axis Z, where the second surface 130b faces the second epitaxial layer 110. The third epitaxial layer 130 is designed to form the top portion 52″ of the main body 52, as discussed more fully hereinafter. The third epitaxial layer 130, together with the substrate 100, the first epitaxial layer 106, and the second epitaxial layer 110, forms the semiconductor body 31. In detail, the third epitaxial layer 130 has, on the third sacrificial layer 128, a thickness along the axis Z equal to the maximum thickness D₁, which is smaller than the minimum thickness D₂ (e.g., the thickness measured along the axis Z between the first surface 130a of the third epitaxial layer 130 and the third sacrificial layer 128).

With reference to FIG. 8H, the piezoelectric structure 54 is formed on the third epitaxial layer 130 so that the piezoelectric structure 54 will overlie the second working trenches 126 and the sacrificial structures 124. In detail, this comprises forming, in succession, via techniques in themselves known: the first electrode 60 (e.g., of metal such as gold or platinum); the piezoelectric layer 62 (of piezoelectric material such as PZT); and the second electrode 61 (e.g., of metal such as gold or platinum). For instance, this is obtained using a fifth mask (similar to the first mask) that covers the first surface 130a of the third epitaxial layer 130, leaving exposed a region of said first surface 130a that overlies the second working trenches 126 and the sacrificial structures 124.

Furthermore, in FIG. 8H a first decoupling trench 132 and one or more etch holes 134 are formed (considered by way of non-limiting example in what follows is the case of an etch hole 134). The first decoupling trench 132 overlies the second blocking layer 102 and extends starting from the first surface 130a of the third epitaxial layer 130 as far as the second blocking layer 102. The etch hole 134 overlies the third sacrificial layer 128 and thus the second working trenches 126 and the sacrificial structures 124 and extends from the first surface 130a of the third epitaxial layer 130 as far as the third sacrificial layer 128, alongside the first decoupling trench 132 along the axis X. For instance, the etch hole 134 overlies one of the second working trenches 126. Formation of the first decoupling trench 132 and of the etch hole 134 is achieved via a third etch (similar to the first etch) performed through a sixth mask (similar to the first mask) that covers the first surface 130a of the third epitaxial layer 130 and the piezoelectric structure 54 and leaves exposed regions of the first surface 130a of the third epitaxial layer 130, which, respectively, overlie the second blocking layer 102 and the third sacrificial layer 128.

With reference to FIG. 8I, optionally and in a way not shown, obtained in a per se known manner are metal contacts and pads, of metal such as gold, coupled to the first electrode 60 and to the second electrode 61 to enable electrical coupling of the piezoelectric structure 54 with the external environment (e.g., with a biasing or measuring apparatus, external to the MEMS device 30).

Further, once again with reference to FIG. 8I, further etches are carried out starting from the second surface 100b of the substrate 100 in order to define the deformable structure 50 (in detail, to decouple it from the anchorage structure 32 comprising part of the substrate 100) and, optionally, to define the seismic mass 72. In particular, a main-cavity etch is carried out starting from the second surface 100b of the substrate 100 to remove portions of the substrate 100 that are aligned along the axis Z with the first blocking layer 104 and the second blocking layer 102 so as to form, respectively, a working cavity 138 and a second decoupling trench 140, which expose the first blocking layer 104 and, respectively, the second blocking layer 102 and form part of the main cavity 57. The main-cavity etch comprises a fifth etch, which will be described more fully in what follows and, optionally, also a thinning of the thickness of the substrate 100 in an area corresponding to the seismic mass 72, as will be described more fully in what follows with reference to a fourth etch.

In greater detail, optionally the fourth etch (e.g., a dry etch, for example a Bosch etch) is initially carried out to form a first (optional) working cavity 136, which extends in the substrate 100 and faces the second surface 100b of the substrate 100. In particular, the first working cavity 136 extends from the second surface 100b of the substrate 100 to the first surface 100a of the substrate 100, without reaching the latter and is aligned along the axis Z with the second working trenches 126, the sacrificial structures 124, and the portions of the first, second, and third epitaxial layers 106, 110, 130 that extend along the axis X between the second working trenches 126, the sacrificial structures 124, and the first decoupling trench 132. For instance, the fourth etch is performed through a seventh mask (similar to the first mask) that covers the second surface 100b of the substrate 100, leaving exposed a region of the second surface 100b, overlying which are the second working trenches 126, the sacrificial structures 124, the first decoupling trench 132, and the portions of the first, second, and third epitaxial layers 106, 110 and 130 that extend along the axis X between the second working trenches 126 and the first decoupling trench 132. The fifth etch thus enables reduction of the thickness along the axis Z of the portion of the substrate 100, overlying which are the portions of the first, second, and third epitaxial layers 106, 110 and 130 that extend along the axis X between the second working trenches 126 and the first decoupling trench 132. The surface of the substrate 100 that delimits, along the axis Z, the first working cavity 136 is referred to in what follows as third surface 100c of the substrate 100.

Furthermore, the fifth etch (similar to the fourth etch) is carried out to form a second working cavity 138 and a second decoupling trench 140 in an area corresponding to the first working cavity 136 (i.e., starting from the third surface 100c of the substrate 100). The second working cavity 138 is aligned, along the axis Z, with the first blocking layer 104 (thus with the second working trenches 126 and the sacrificial structures 124) and extends from the third surface 100c of the substrate 100 (alternatively, from the second surface 100b when the fourth etch is not carried out) as far as the first blocking layer 104. The second decoupling trench 140 is aligned, along the axis Z, with the second blocking layer 102 (thus with the first decoupling trench 132), and extends starting from the third surface 100c of the substrate 100 (alternatively, from the second surface 100b when the fourth etch is not carried out) as far as the second blocking layer 102.

In this way, the first working cavity 136 and the second working cavity 138 form part of the main cavity 57 over which the deformable structure 50 and the seismic mass 72 are suspended. The portions of the first, second, and third epitaxial layers 106, 110 and 130 that extend along the axis X between the second working trenches 126 and the first decoupling trench 132 form, together with the underlying portion of the substrate 100 aligned thereto, along the axis Z, the seismic mass 72. The portions of the first and third epitaxial layers 106 and 130 that overlie the second working cavity 138 form, together with the piezoelectric structure 54, the deformable structure 50. The remaining portions of the substrate 100 and of the first, second, and third epitaxial layers 106, 110 and 130 form the anchorage structure 32 to which the deformable structure 50 is constrained. In fact, as shown in FIG. 6, the first and second decoupling trenches 132, 140 surround, in a plane parallel to the plane XY, the deformable structure 50 and the seismic mass 72 so as to decouple the seismic mass 72 altogether from the anchorage structure 32 and partially decouple the deformable structure 50 from the anchorage structure 32, leaving the seismic mass 72 and the deformable structure 50 connected together only at the first end 50′ of the deformable structure 50.

In greater detail, the fifth etch is carried out via the use of an eighth mask (similar to the first mask) that covers the second and third surfaces 100b, 100c of the substrate 100 and that exposes regions of the third surface 100b of the substrate 100 that are aligned, along the axis Z, to the first decoupling trench 132, to the second working trenches 126, and to the sacrificial structures 124.

Furthermore, with reference to FIG. 8I the buried cavity 65 is formed. In particular, this is obtained by carrying out a sixth etch (or buried-cavity etch) designed to remove the third sacrificial layer 128, the sacrificial structures 124, and the first sacrificial layer 108. The sixth etch is, for example, a wet etch (e.g., HF-based) and is performed through the etch hole 134, which enables the chemical agent to reach the third sacrificial layer 128, the sacrificial structures 124, and the first sacrificial layer 108 to remove them. In detail, the sixth etch selectively removes the oxide and not the silicon. In other words, the third epitaxial layer 130 operates as mask for the sixth etch.

The sixth etch likewise removes also the second blocking layer 102 exposed via the first decoupling trench 132, as well as the first blocking layer 104 exposed by the main cavity 57 (in particular, by the second working cavity 138). Consequently, the first and second decoupling trenches 132, 140 extend in continuity with respect to one another, and thus the deformable structure and the seismic mass 2 are decoupled from the anchorage structure 32, except for the first end 50′ of the deformable structure 50.

At the end of these manufacturing steps the MEMS device 30 illustrated, for example, in FIGS. 6 and 7 is obtained.

In particular, the manufacturing steps previously discussed have been described with reference to a cross-section of the MEMS device 30 taken along the line of section A-A, where the supporting elements 70 are not shown; however, they apply in a similar way also to formation of the supporting elements 70, if present (for example, with reference to the manufacture of the MEMS device 30 along the line of section C-C shown in FIG. 6 and passing through the supporting elements 70, in FIG. 8D a plurality of sets of first working trenches 112 are formed, instead of just one set of first working trenches 112, these sets being arranged alongside one another and at a distance apart along the axis X, where each set leads to formation of a respective opening 76 and where each portion of the second epitaxial layer 110 comprised between two sets adjacent to one another of first working trenches 112 forms a respective supporting element 70).

Otherwise, in the case where the MEMS device 30 does not comprise the seismic mass 72, the main-cavity etch is carried out starting from the second surface 100b of the substrate 100 to remove a portion of the substrate 100 that is aligned, along the axis Z, with the first blocking layer 104 and the second blocking layer 102 so as to expose the first blocking layer 104, the second blocking layer 102, and a portion of the first epitaxial layer 106 that extends, along the axis X, between the first blocking layer 104 and the second blocking layer 102. In other words, the fourth etch may be carried out so that the first working cavity 136 reaches the first epitaxial layer 106 and consequently the first and second blocking layers 104 and 102, and the fifth etch is not carried out. In addition, in this case the first decoupling trench 132 may extend at a shorter distance, along the axis X, from the buried cavity 65 (e.g., less than approximately 10 μm).

From an examination of the characteristics of the disclosure provided according to the present disclosure the advantages that it affords are evident.

In particular, the deformable structure 50 comprising the buried cavity 65 increases, given the same mass of solid material used, the h_{piezo-neutrax} as compared with known solutions. This makes it possible to increase the EMCF_{ψ} without having to increase the mass of the solid material present in the deformable structure 50 and thus without having to increase the stiffness of the deformable structure 50. Consequently, it is possible to increase the EMCF_{ψ} without modifying the mechanical and electrical properties of the MEMS device 30, and this is achieved without having to act on the piezoelectric structure 54 (e.g., by changing the piezoelectric material) and without entailing an additional encumbrance or a specific shape of the deformable structure 50 in a plane parallel to the plane XY. This occurs thanks to the buried cavity 65, which causes the neutral plane 56 and the midplane 58 do not coincide.

Furthermore, all the known solutions described previously in order to increase the EMCF_{ψ} may in any case be used in addition to the present deformable structure 50 (e.g., the deformable structure 50 with tapered shape or different materials for the piezoelectric layer 62). Consequently, this solution is not in contrast with the known solutions but may be combined with them to increase further the EMCF_{ψ}.

For instance, it has been found that the present deformable structure 50 makes it possible to increase significantly the performance of the MEMS device 30 as compared to the known solutions, in particular with increases of even approximately 40% of the EMCF_{ψ}, which lead, for example, to similar increases of the maximum deformation that may be obtained when the MEMS device 30 operates as actuator, to similar increases of the maximum difference of electrical potential between the electrodes 60 and 61 when the MEMS device 30 operates as sensor and to increases of even approximately 106% of the power supplied by the MEMS device 30 when it is used as energy harvester.

Finally, it is clear that modifications and variations may be made to the disclosure described and illustrated herein, without thereby departing from the scope of the present disclosure, as defined in the annexed claims.

For instance, the various embodiments described may be combined together so as to provide further solutions.

Furthermore, the arrangement of the supporting structures 70 described previously with reference to FIG. 6 likewise applies also to the case where the supporting elements 70 have a different shape and, for example, are columns.

At least one embodiment of the MEMS device (30) of the present disclosure may be summarized as including: a semiconductor body (31) defining a main cavity (57) and forming an anchorage structure (32); and a first deformable structure (50) having a direction of main extension (55) along a first axis (X), and a first end (50′) and a second end (50″) that are opposite to one another along the first axis (X), the first deformable structure (50) being fixed to the anchorage structure (32) via the first end (50′) so as to be suspended over the main cavity (57), wherein the second end (50″) is configured to oscillate, with respect to the anchorage structure (32), in a direction of oscillation parallel to a second axis (Z) orthogonal to the first axis (X), wherein the first deformable structure (50) comprises a main body (52), having a first outer surface (52a) and a second outer surface (52b) opposite to one another along the second axis (Z), and a piezoelectric structure (54) extending over the first outer surface (52a) of the main body (52), wherein the main body (52) comprises a bottom portion (52′) and a top portion (52″) that are coupled together and that delimit along the second axis (Z) a first buried cavity (65) of the main body (52), which is aligned with the piezoelectric structure (54) along the second axis (Z), the top portion (52″) of the main body (52) defining the first outer surface (52a) of the main body (52) and the bottom portion (52′) of the main body (52) defining the second outer surface (52b) of the main body (52), and wherein a maximum thickness (D₁) of the top portion (52″) of the main body (52) along the second axis (Z) is smaller than a minimum thickness (D₂) of the bottom portion (52′) of the main body (52) along the second axis (Z).

The top portion (52″) has a first inner surface (65a) opposite along the second axis (Z) to the first outer surface (52a) with respect to the top portion (52″), and the bottom portion (52′) has a second inner surface (65b) opposite along the second axis (Z) to the second outer surface (52b) with respect to the bottom portion (52′), the first inner surface (65a) and the second inner surface (65b) facing the first buried cavity (65), wherein the maximum thickness (D₁) of the top portion (52″) is a maximum distance between the first inner surface (65a) and the first outer surface (52a), and the minimum thickness (D₂) of the bottom portion (52′) is a minimum distance between the second inner surface (65b) and the second outer surface (52b).

The main body (52) further includes one or more supporting elements (70), which extend in the first buried cavity (65) between the bottom portion (52′) and the top portion (52″) so as to join together the bottom portion (52′) and the top portion (52″) along the second axis (Z).

The main body (52) further includes a plurality of said supporting elements (70), the supporting elements (70) being supporting columns or structures.

The supporting elements (70) are aligned with one another in sets, each set having the respective supporting elements (70) that are aligned with one another along a respective axis of alignment (74) parallel to a third axis (Y) orthogonal to the first axis (X) and to the second axis (Z), wherein each pair of sets of supporting elements (70) that are adjacent to one another delimit along the third axis (Y) a respective channel (78) that has its main extension parallel to the first axis (X), and wherein, in each set, the supporting elements (70) are arranged discretely along the respective axis of alignment (74) so as to form, for each pair of supporting elements (70) adjacent to one another in said set, a respective opening (76) that arranges apart from one another the supporting elements (70) of said pair of supporting elements (70), wherein the openings (76) arrange the channels (78) in communication with one another and form, together with the channels (78), the first buried cavity (65).

The supporting elements (70) of each set are staggered, parallel to the third axis (Y), with respect to the supporting elements (70) of the adjacent set or of the pair of adjacent sets so that the openings (76) of each set are staggered, parallel to the third axis (Y), with respect to the openings (76) of the adjacent set or of the pair of adjacent sets.

The MEMS device further includes a seismic mass (72) fixed to the second end (50″) of the deformable structure (50) so as to be suspended over the main cavity (57), the seismic mass (72) being configured to oscillate, with respect to the anchorage structure (32), along the direction of oscillation.

The bottom portion (52′) and the top portion (52″) further delimit along the second axis (Z) at least one second buried cavity (65) of the main body (52), which is aligned with the piezoelectric structure (54) along the second axis (Z) and is arranged alongside the first buried cavity (65) orthogonally to the second axis (Z).

The MEMS device further includes at least one second deformable structure (50) having a respective direction of main extension (55) and a respective first end (50′) and a respective second end (50″) that are opposite to one another in the direction of main extension (55) of the second deformable structure (50), the second deformable structure (50) being fixed to the anchorage structure (32) via the respective first end (50′) so as to be suspended over the main cavity (57), wherein the second end (50″) of the second deformable structure (50) is configured to oscillate, with respect to the anchorage structure (32), parallel to the direction of oscillation, wherein the second deformable structure (50) comprises a respective main body (52), having a respective first outer surface (52a) and a respective second outer surface (52b) opposite to one another along the second axis (Z), and a respective piezoelectric structure (54) extending on the first outer surface (52a) of the main body (52) of the second deformable structure (50), wherein the main body (52) of the second deformable structure (50) comprises a respective bottom portion (52′) and a respective top portion (52″) that are coupled together and that delimit along the second axis (Z) a respective first buried cavity (65) of the main body (52) of the second deformable structure (50), which is aligned with the piezoelectric structure (54) of the second deformable structure (50) along the second axis (Z), the top portion (52″) of the main body (52) of the second deformable structure (50) defining the first outer surface (52a) of the main body (52) of the second deformable structure (50), and the bottom portion (52′) of the main body (52) of the second deformable structure (50) defining the second outer surface (52b) of the main body (52) of the second deformable structure (50), and wherein a respective maximum thickness (D₁) of the top portion (52″) of the main body (52) of the second deformable structure (50) along the second axis (Z) is smaller than a respective minimum thickness (D₂) of the bottom portion (52′) of the main body (52) of the second deformable structure (50) along the second axis (Z).

At least one embodiment of a manufacturing process of a MEMS device (30) of the present disclosure may be summarized as including: a semiconductor body (31), which defines a main cavity (57) and forms an anchorage structure (32); and a first deformable structure (50), having a direction of main extension (55) along a first axis (X), and a first end (50′) and a second end (50″) that are opposite to one another along the first axis (X), the first deformable structure (50) being fixed to the anchorage structure (32) via the first end (50′) so as to be suspended over the main cavity (57), and the second end (50″) being configured to oscillate, with respect to the anchorage structure (32), in a direction of oscillation parallel to a second axis (Z) orthogonal to the first axis (X), the manufacturing process comprising the steps of: forming, on a first surface (100a) of a substrate (100) of semiconductor material, a main body (52) of the first deformable structure (50), comprising semiconductor material and having a first outer surface (52a) and a second outer surface (52b) opposite to one another along the second axis (Z), the semiconductor body (31) comprising the substrate (100); forming, in the main body (52), a first buried cavity (65) delimited along the second axis (Z) by a bottom portion (52′) and by a top portion (52″) of the main body (52), coupled together, wherein the top portion (52″) of the main body (52) defines the first outer surface (52a) of the main body (52), and the bottom portion (52′) of the main body (52) defines the second outer surface (52b) of the main body (52) and wherein a maximum thickness (D₁) of the top portion (52″) of the main body (52) along the second axis (Z) is smaller than a minimum thickness (D₂) of the bottom portion (52′) of the main body (52) along the second axis (Z); forming, on the first outer surface (52a), a piezoelectric structure (54) of the first deformable structure (50), the piezoelectric structure (54) being aligned along the second axis (Z) to the first buried cavity (65); and forming in the substrate (100), starting from a second surface (100b) of the substrate (100) opposite to the first surface (100a) of the substrate (100) along the second axis (Z), the main cavity (57) so as to define the anchorage structure (32) and to have the first deformable structure (50) fixed to the anchorage structure (32) via the first end (50′) and suspended over the main cavity (57).

The step of forming the main body (52) includes: forming, on the first surface (100a) of the substrate (100), a first blocking layer (104) of insulating material; forming, on the first surface (100a) of the substrate (100) and on the first blocking layer (104), a first epitaxial layer (106) of semiconductor material, the first epitaxial layer (106) forming the bottom portion (52′) of the main body (52); forming, on the first epitaxial layer (106), a first sacrificial layer (108) of insulating material, overlying the first blocking layer (104) along the second axis (Z); forming, on the first epitaxial layer (106) and on the first sacrificial layer (108), a second epitaxial layer (110) of semiconductor material, the second epitaxial layer (110) having a respective first surface (110a) and a respective second surface (110b) opposite to one another along the second axis (Z), the second surface (110b) of the second epitaxial layer (110) facing the first epitaxial layer (106) and the first sacrificial layer (108); and forming, on the second epitaxial layer (110), a third epitaxial layer (130) of semiconductor material, the third epitaxial layer (130) forming the top portion (52″) of the main body (52).

The step of forming the first buried cavity (65) comprises, after forming the second epitaxial layer (110) and before forming the third epitaxial layer (130): forming, in the second epitaxial layer (110) and via a first etch, a plurality of first working trenches (112) that overlie, along the second axis (Z), the first sacrificial layer (108) and extend through the second epitaxial layer (110) from the first surface (110a) of the second epitaxial layer (110) to the second surface (110b) of the second epitaxial layer (110); forming, on the second epitaxial layer (110) and so as to fill the first working trenches (112), a second sacrificial layer (114) of insulating material, wherein portions of the second sacrificial layer (114) present in the first working trenches (112) form respective sacrificial elements (116) that extend through the second epitaxial layer (110) from the first surface (110a) of the second epitaxial layer (110) to the second surface (110b) of the second epitaxial layer (110), wherein portions of the second epitaxial layer (110) arranged along the first axis (X) between sacrificial elements (116) adjacent to one another form respective sacrificial portions (118) of the second epitaxial layer (110), the second sacrificial layer (114) having, for each sacrificial portion (118), a respective etch opening (122), which exposes the respective sacrificial portion (118); removing, via a second etch made through the etch openings (122), the sacrificial portions (118) to form respective second working trenches (126) that extend from the etch openings (122) to the first sacrificial layer (108); and forming, on the sacrificial elements (116) and on the second working trenches (126), a third sacrificial layer (128) of insulating material, which covers the etch openings (122), wherein the step of forming the third epitaxial layer (130) on the second epitaxial layer (110) comprises forming the third epitaxial layer (130) also on the third sacrificial layer (128), and wherein the step of forming the first buried cavity (65) further comprises, after forming the third epitaxial layer (130): forming, in the third epitaxial layer (130) and via a third etch, one or more etch holes (134), which overlie, along the second axis (Z), the third sacrificial layer (128) and extend through the third epitaxial layer (130) to the third sacrificial layer (128); and removing, via a buried-cavity etch performed through the one or more etch holes (134), the third sacrificial layer (128), the second sacrificial layer (114), and the first sacrificial layer (108) to form the first buried cavity (65).

The step of forming the first blocking layer (104) further comprises forming, on the first surface (100a) of the substrate (100) and alongside the first blocking layer (104) along the first axis (X), a second blocking layer (102) of insulating material; wherein the step of forming the first epitaxial layer (106) comprises forming the first epitaxial layer (106) also on the second blocking layer (102), wherein the step of forming, via the third etch, the one or more etch holes (134) further comprises forming a first decoupling trench (132), which overlies, along the second axis (Z), the second blocking layer (102) and which extends through the third epitaxial layer (130) to the second blocking layer (102), alongside, along the first axis (X), the one or more etch holes (134), the second sacrificial layer (114), and the third sacrificial layer (128), and wherein the step of removing, via the buried-cavity etch, the third sacrificial layer (128), the second sacrificial layer (114), and the first sacrificial layer (108) further comprises removing the second blocking layer (102) by carrying out a buried-cavity etch also through the first decoupling trench (132).

The step of forming the main cavity (57) comprises, prior to removal of the third sacrificial layer (128), the second sacrificial layer (114), the first sacrificial layer (108), and the second blocking layer (102) via the buried-cavity etch, removing, via a main-cavity etch carried out starting from the second surface (100b) of the substrate (100), a portion of the substrate (100) that is aligned along the second axis (Z) with the first blocking layer (104) and the second blocking layer (102) so as to expose the first blocking layer (104), the second blocking layer (102), and a portion of the first epitaxial layer (106) that extends, along the first axis (X), between the first blocking layer (104) and the second blocking layer (102), and wherein the step of removing, via the buried-cavity etch, the third sacrificial layer (128), the second sacrificial layer (114), the first sacrificial layer (108), and the second blocking layer (102) further comprises removing the first blocking layer (104) by carrying out the buried-cavity etch also through the main cavity (57).

The step of forming the main cavity (57) comprises, prior to removal of the third sacrificial layer (128), the second sacrificial layer (114), the first sacrificial layer (108), and the second blocking layer (102) via the buried-cavity etch: removing, via a main-cavity etch carried out starting from the second surface (100b) of the substrate (100), portions of the substrate (100) that are aligned along the second axis (Z) with the first blocking layer (104) and the second blocking layer (102) so as to form, respectively, a working cavity (138) and a second decoupling trench (140), which expose the first blocking layer (104) and the second blocking layer (102), respectively, the working cavity (138) and the second decoupling trench (140) forming part of the main cavity (57), and wherein the step of removing, via the buried-cavity etch, the third sacrificial layer (128), the second sacrificial layer (114), the first sacrificial layer (108), and the second blocking layer (102) further comprises removing the first blocking layer (104) by carrying out the buried-cavity etch also through the main cavity (57).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A MEMS device, comprising:
a semiconductor body defining a main cavity and forming an anchorage structure; and
a first deformable structure having a direction of main extension along a first axis, and a first end and a second end that are opposite to one another along the first axis, the first deformable structure being fixed to the anchorage structure via the first end so as to be suspended over the main cavity,
wherein the second end is configured to oscillate, with respect to the anchorage structure, in a direction of oscillation parallel to a second axis orthogonal to the first axis,
wherein the first deformable structure includes a main body having a first outer surface, a second outer surface opposite to the first outer surface along the second axis, and a piezoelectric structure extending over the first outer surface of the main body,
wherein the main body includes a bottom portion and a top portion that are coupled together and that delimit along the second axis a first buried cavity of the main body aligned with the piezoelectric structure along the second axis, the top portion of the main body defining the first outer surface of the main body and the bottom portion of the main body defining the second outer surface of the main body, and
wherein a maximum thickness of the top portion of the main body along the second axis is smaller than a minimum thickness of the bottom portion of the main body along the second axis.

2. The MEMS device according to claim 1, wherein the top portion has a first inner surface opposite along the second axis to the first outer surface with respect to the top portion, and the bottom portion has a second inner surface opposite along the second axis to the second outer surface with respect to the bottom portion, the first inner surface and the second inner surface facing the first buried cavity,
wherein the maximum thickness of the top portion is a maximum distance between the first inner surface and the first outer surface, and the minimum thickness of the bottom portion is a minimum distance between the second inner surface and the second outer surface.

3. The MEMS device according to claim 1, wherein the main body further includes one or more supporting elements, which extend in the first buried cavity between the bottom portion and the top portion so as to join together the bottom portion and the top portion along the second axis.

4. The MEMS device according to claim 3, wherein the main body includes a plurality of the supporting elements, the supporting elements being supporting columns or structures.

5. The MEMS device according to claim 4, wherein the supporting elements are aligned with one another in sets, each set having the respective supporting elements that are aligned with one another along a respective axis of alignment parallel to a third axis orthogonal to the first axis and to the second axis,
wherein each pair of sets of supporting elements that are adjacent to one another delimit along the third axis a respective channel that has its main extension parallel to the first axis, and
wherein, in each set, the supporting elements are arranged discretely along the respective axis of alignment so as to form, for each pair of supporting elements adjacent to one another in the set, a respective opening that arranges apart from one another the supporting elements of the pair of supporting elements,
wherein the openings arrange the channels in communication with one another and form, together with the channels, the first buried cavity.

6. The MEMS device according to claim 5, wherein the supporting elements of each set are staggered, parallel to the third axis, with respect to the supporting elements of the adjacent set or of the pair of adjacent sets so that the openings of each set are staggered, parallel to the third axis, with respect to the openings of the adjacent set or of the pair of adjacent sets.

7. The MEMS device according to claim 1, further comprising a seismic mass fixed to the second end of the deformable structure so as to be suspended over the main cavity, the seismic mass being configured to oscillate, with respect to the anchorage structure, along the direction of oscillation.

8. The MEMS device according to claim 1, wherein the bottom portion and the top portion further delimit along the second axis at least one second buried cavity of the main body, which is aligned with the piezoelectric structure along the second axis and is arranged alongside the first buried cavity orthogonally to the second axis.

9. The MEMS device according to claim 1, further comprising at least one second deformable structure having a respective direction of main extension and a respective first end and a respective second end that are opposite to one another in the direction of main extension of the second deformable structure, the second deformable structure being fixed to the anchorage structure via the respective first end so as to be suspended over the main cavity,
wherein the second end of the second deformable structure is configured to oscillate, with respect to the anchorage structure, parallel to the direction of oscillation,
wherein the second deformable structure comprises a respective main body, having a respective first outer surface and a respective second outer surface opposite to one another along the second axis, and a respective piezoelectric structure extending on the first outer surface of the main body of the second deformable structure,
wherein the main body of the second deformable structure comprises a respective bottom portion and a respective top portion that are coupled together and that delimit along the second axis a respective first buried cavity of the main body of the second deformable structure, which is aligned with the piezoelectric structure of the second deformable structure along the second axis, the top portion of the main body of the second deformable structure defining the first outer surface of the main body of the second deformable structure, and the bottom portion of the main body of the second deformable structure defining the second outer surface of the main body of the second deformable structure, and
wherein a respective maximum thickness of the top portion of the main body of the second deformable structure along the second axis is smaller than a respective minimum thickness of the bottom portion of the main body of the second deformable structure along the second axis.

10. A manufacturing process of a MEMS device that comprises:
a semiconductor body, which defines a main cavity and forms an anchorage structure; and
a first deformable structure, having a direction of main extension along a first axis, and a first end and a second end that are opposite to one another along the first axis, the first deformable structure being fixed to the anchorage structure via the first end so as to be suspended over the main cavity, and the second end being configured to oscillate, with respect to the anchorage structure, in a direction of oscillation parallel to a second axis orthogonal to the first axis,
the manufacturing process comprising the steps of:
forming, on a first surface of a substrate of semiconductor material, a main body of the first deformable structure, including semiconductor material and having a first outer surface and a second outer surface opposite to one another along the second axis, the semiconductor body including the substrate;
forming, in the main body, a first buried cavity delimited along the second axis by a bottom portion and by a top portion of the main body, coupled together, wherein the top portion of the main body defines the first outer surface of the main body, and the bottom portion of the main body defines the second outer surface of the main body and wherein a maximum thickness of the top portion of the main body along the second axis is smaller than a minimum thickness of the bottom portion of the main body along the second axis;
forming, on the first outer surface, a piezoelectric structure of the first deformable structure, the piezoelectric structure being aligned along the second axis to the first buried cavity; and
forming in the substrate, starting from a second surface of the substrate opposite to the first surface of the substrate along the second axis, the main cavity so as to define the anchorage structure and to have the first deformable structure fixed to the anchorage structure via the first end and suspended over the main cavity.

11. The manufacturing process according to claim 10, wherein the step of forming the main body includes:
forming, on the first surface of the substrate, a first blocking layer of insulating material;
forming, on the first surface of the substrate and on the first blocking layer, a first epitaxial layer of semiconductor material, the first epitaxial layer forming the bottom portion of the main body;
forming, on the first epitaxial layer, a first sacrificial layer of insulating material, overlying the first blocking layer along the second axis;
forming, on the first epitaxial layer and on the first sacrificial layer, a second epitaxial layer of semiconductor material, the second epitaxial layer having a respective first surface and a respective second surface opposite to one another along the second axis, the second surface of the second epitaxial layer facing the first epitaxial layer and the first sacrificial layer; and
forming, on the second epitaxial layer, a third epitaxial layer of semiconductor material, the third epitaxial layer forming the top portion of the main body.

12. The manufacturing process according to claim 11, wherein the step of forming the first buried cavity comprises, after forming the second epitaxial layer and before forming the third epitaxial layer:
forming, in the second epitaxial layer and via a first etch, a plurality of first working trenches that overlie, along the second axis, the first sacrificial layer and extend through the second epitaxial layer from the first surface of the second epitaxial layer to the second surface of the second epitaxial layer;
forming, on the second epitaxial layer and so as to fill the first working trenches, a second sacrificial layer of insulating material, wherein portions of the second sacrificial layer present in the first working trenches form respective sacrificial elements that extend through the second epitaxial layer from the first surface of the second epitaxial layer to the second surface of the second epitaxial layer, wherein portions of the second epitaxial layer arranged along the first axis between sacrificial elements adjacent to one another form respective sacrificial portions of the second epitaxial layer, the second sacrificial layer having, for each sacrificial portion, a respective etch opening, which exposes the respective sacrificial portion;
removing, via a second etch made through the etch openings, the sacrificial portions to form respective second working trenches that extend from the etch openings to the first sacrificial layer; and
forming, on the sacrificial elements and on the second working trenches, a third sacrificial layer of insulating material, which covers the etch openings,
wherein the step of forming the third epitaxial layer on the second epitaxial layer comprises forming the third epitaxial layer also on the third sacrificial layer, and
wherein the step of forming the first buried cavity further includes, after forming the third epitaxial layer:
forming, in the third epitaxial layer and via a third etch, one or more etch holes, which overlie, along the second axis, the third sacrificial layer and extend through the third epitaxial layer to the third sacrificial layer; and
removing, via a buried-cavity etch performed through the one or more etch holes, the third sacrificial layer, the second sacrificial layer, and the first sacrificial layer to form the first buried cavity.

13. The manufacturing process according to claim 12, wherein the step of forming the first blocking layer further includes forming, on the first surface of the substrate and alongside the first blocking layer along the first axis, a second blocking layer of insulating material;
wherein the step of forming the first epitaxial layer includes forming the first epitaxial layer also on the second blocking layer,
wherein the step of forming, via the third etch, the one or more etch holes further comprises forming a first decoupling trench, which overlies, along the second axis, the second blocking layer and which extends through the third epitaxial layer to the second blocking layer, alongside, along the first axis, the one or more etch holes, the second sacrificial layer, and the third sacrificial layer, and
wherein the step of removing, via the buried-cavity etch, the third sacrificial layer, the second sacrificial layer, and the first sacrificial layer further comprises removing the second blocking layer by carrying out a buried-cavity etch also through the first decoupling trench.

14. The manufacturing process according to claim 13, wherein the step of forming the main cavity comprises, prior to removal of the third sacrificial layer, the second sacrificial layer, the first sacrificial layer, and the second blocking layer via the buried-cavity etch, removing, via a main-cavity etch carried out starting from the second surface of the substrate, a portion of the substrate that is aligned along the second axis with the first blocking layer and the second blocking layer so as to expose the first blocking layer, the second blocking layer, and a portion of the first epitaxial layer that extends, along the first axis, between the first blocking layer and the second blocking layer, and
wherein the step of removing, via the buried-cavity etch, the third sacrificial layer, the second sacrificial layer, the first sacrificial layer, and the second blocking layer further comprises removing the first blocking layer by carrying out the buried-cavity etch also through the main cavity.

15. The manufacturing process according to claim 13, wherein the step of forming the main cavity includes, prior to removal of the third sacrificial layer, the second sacrificial layer, the first sacrificial layer, and the second blocking layer via the buried-cavity etch:
removing, via a main-cavity etch carried out starting from the second surface of the substrate, portions of the substrate that are aligned along the second axis with the first blocking layer and the second blocking layer so as to form, respectively, a working cavity and a second decoupling trench, which expose the first blocking layer and the second blocking layer, respectively, the working cavity and the second decoupling trench forming part of the main cavity, and
wherein the step of removing, via the buried-cavity etch, the third sacrificial layer, the second sacrificial layer, the first sacrificial layer, and the second blocking layer further includes removing the first blocking layer by carrying out the buried-cavity etch also through the main cavity.

16-20. (canceled)

21. A MEMS device, comprising:
a main cavity;
a semiconductor body including an anchorage structure that at least partially delimits the main cavity;
a deformable structure coupled to the anchorage structure, the deformable structure extends from the anchorage structure and overlaps the main cavity, and the deformable structure includes:
a first outer surface; and
a second outer surface opposite to the first outer surface;
a buried cavity within the deformable structure between the first outer surface and the second outer surface, the buried cavity includes a first side and a second side opposite to the first side, and the first side is closer to the first outer surface than the second outer surface;
a plurality of supporting elements within the buried cavity, the plurality of supporting elements extend from the second side to the first side of the buried cavity.

22. The device of claim 21, further comprising a plurality of openings that are between adjacent pairs of the plurality of supporting elements, and wherein:
the buried cavity further includes a plurality of channels defined by the plurality of supporting elements; and
the plurality of openings extend between adjacent pairs of the plurality of channels of the buried cavity.

23. The device of claim 21, further comprising a seismic mass at an end of the deformable structure spaced apart from the anchorage structure.

24. The device of claim 21, wherein the buried cavity is closer to the first outer surface than the second outer surface of the deformable structure.

25. The device of claim 21, wherein the deformable structure includes a resting position in which a neutral plane of the deformable structure is offset from a midplane of the deformable structure.
